(19) United States
(12) Patent Application Publication
(10) Pub. No.: US 2024/0012749 A1
(43) Pub. Date: Jan. 11, 2024

(54) STORAGE AND TRANSDUCTION OF QUANTUM INFORMATION

(71) Applicant: PHOTONIC INC., Coquitlam (CA)

(72) Inventors: Stephanie SIMMONS, Burnaby (CA); Evan MACQUARRIE, Burnaby (CA)

(21) Appl. No.: 18/006,512

(22) PCT Filed: Jul. 28, 2021
(86) PCT No.: PCT/CA2021/051056

§ 371 Date: Jan. 23, 2023

Related U.S. Application Data
(60) Provisional application No. 63/057,796, filed on Jul. 28, 2020.

(51) Int. Cl. G06F 12/02

(52) U.S. Cl. CPC G06F 12/023

(57) ABSTRACT

Methods and apparatus for storing and transducing quantum information provide a luminescent center in silicon controllably coupled to undergo quantum interactions with a first qubit such as a superconducting qubit. The luminescent center may be a T center or an ensemble of T centers, for example. The same or different quantum information may be stored in an unpaired electron or hole spin, and/or one or more of three nuclear spins of the T center. The stored quantum information may be later returned to the first qubit or transferred to an optical photon state.

### CROSS-REFERENCE TO RELATED APPLICATIONS

This application claims priority from U.S. application No. 63/057,796 filed 28 Jul. 2020 and entitled STORAGE AND TRANSDUCTION OF QUANTUM INFORMATION which is hereby incorporated herein by reference for all purposes. For purposes of the United States of America, this application claims the benefit under 35 U.S.C. § 119 of U.S. application No. 63/057,796 filed 28 Jul. 2020 and entitled STORAGE AND TRANSDUCTION OF QUANTUM INFORMATION.

### FIELD

The present technology relates to the storage and manipulation of quantum information. Some embodiments provide methods and apparatus for transducing quantum information between qubits having quantum states separated by different energies. For example, an application of the present technology is to transduce quantum information from qubits having energy level separations corresponding to microwave wavelengths to optical photons. Another application of the present technology is to store quantum information. Another application of the present invention is to create quantum entanglement among plural qubits.

### BACKGROUND

Quantum computing has the potential to revolutionize computer science. In quantum computing states of a quantum system are used to represent data. For example, the direction of spin of a particle, such as an electron, relative to a magnetic field may represent a binary value of 1 or 0 depending on whether the spin is oriented parallel to (spin down) or anti-parallel to (spin up) a magnetic field. One advantage of quantum computing is that a quantum system may be in a superposition of states. For example, in some sense the quantum system may simultaneously be spin up and spin down. Another advantage of quantum computing comes from the fact that the states of different quantum systems may be entangled.

One difficulty in making quantum computers is that after a quantum system is set to be in a particular desired state and also while the quantum system is being manipulated in an attempt to place it in the desired state the quantum system may lose coherence by interacting with its environment. This results in the quantum system no longer being in the desired state. Some quantum systems undergo decoherence in very short times (e.g. times on the order of a nanosecond). The effects of decoherence on a particular quantum system may be reduced by keeping a quantum system at very cold (e.g. mK) temperatures.

There remains a need for technological advances that will further the progress of quantum computing.

### Definitions

“Quantum system” is a system that has two or more states and can exist in a superposition of the two or more states. A quantum system may, for example comprise a particle such as an electron, proton, neutron, atomic nucleus, atom, group of atoms, pseudo particle (e.g. a phonon, exciton, magneton), photon, or the like.

“Quantum interaction” includes interactions between quantum states of two or more qubits. Examples of quantum interactions include state transfer interactions and quantum entangling operations.

“Quantum coherence” means the degree to which the relationship between the phases of different quantum states of a quantum system, for example a qubit, is preserved.

“Quantum decoherence” is the change in the quantum state of a quantum system that results from interactions between the system and its environment.

“Entanglement” when applied to two or more quantum systems means that the quantum state of any one of the entangled quantum systems cannot be described independently of the state of the other one(s) of the entangled quantum systems.

“Luminescent center” means a quantum system that has an excited state which can decay to a lower energy state with the emission of an optical photon by a transition which has a transition dipole moment of at least 0.1 Debye. In preferred embodiments the luminescent center, when in the excited state will undergo the transition in 50 μs or less and emit the optical photon with a relatively high probability (e.g. 1% or greater).

“Optical photon” means a photon of electromagnetic radiation that has a wavelength in the range between far infrared and ultraviolet. Photons having wavelengths in the range of 15 μm to 10 nm are examples of optical photons. Photons having wavelengths in the range of 2 μm to 380 nm are examples of optical photons.

“Qubit” means a quantum system that can exist in a superposition of states that can represent data. An example of a qubit is the quantum spin of a particle that can be oriented parallel to (“spin down”) or anti-parallel to (“spin up”) a magnetic field. The spin up state may, for example, be associated with a logical “1” and the spin down state may be associated with a logical “0”.

“Quantum measurement” means a process by which a value is determined for a measurable quantity of a quantum system. An example of quantum measurement is a process that determines whether a spin of a quantum particle is spin up or spin down. Where a quantum system is in a superposition of quantum states and the measurable quantity has a different value for each of the quantum states then a result of quantum measurement is that the quantum system will be in the one of the quantum states corresponding to the determined value immediately after the quantum measurement.

“Superposition” when applied to a quantum particle or other quantum system means that the quantum system exists in two or more separate quantum states at the same time. For example, a quantum particle that has non-zero spin in a magnetic field may simultaneously be in two different spin states.

### SUMMARY

The present technology has various aspects. These include, without limitation:
systems and methods for extending coherence times of qubits in quantum computers;
systems and methods for providing data to and reading data from qubits in quantum computers;
systems and methods for using optical photons to interact with qubits in which states are separated by sub-optical energies;
systems and methods for quantum computing;
systems and methods for entangling microwave and optical photons; These aspects may be applied individually or in any combinations.

One aspect of the invention provides a method for storing quantum information. The method comprises providing a first qubit in a first quantum state that encodes first quantum information. The first qubit has first and second quantized energy levels separated by an energy ΔΔE_{SQ} corresponding to a microwave frequency. In some embodiments the first qubit comprises a superconducting qubit. The method comprises coupling the first qubit to a first luminescent center in silicon by way of a microwave photon state such that quantum states of the first qubit and the first luminescent center undergo a quantum interaction wherein the quantum state of the first luminescent center encodes the first quantum information.

Some embodiments comprise uncoupling the first qubit from the first luminescent center.

Some embodiments comprise coupling the first qubit to the first luminescent center for a time that is substantially equal to n half periods of a two qubit Rabi frequency of the first qubit and the first luminescent center wherein n is an odd integer.

In some embodiments the first luminescent center has first and second quantized energy levels separated by an energy ΔE_{LC1} and coupling the first qubit to the first luminescent center comprises adjusting one or both of the energy ΔE_{LC1} and the energy ΔE_{SQ} so that ΔE_{LC1} and ΔE_{SQ} are substantially equal.

Some embodiments comprise adjusting the energy ΔE_{LC1} by applying an electric field to the first luminescent center. Some embodiments comprise adjusting the energy ΔE_{LC1} by applying an RF driving signal to the first luminescent center. Some embodiments comprise adjusting the energy ΔE_{LC1} by applying a strain to the silicon in which the first luminescent center is located. In some embodiments the first luminescent center is in a magnetic field and the method comprises adjusting the energy ΔE_{LC1} by varying a strength of the magnetic field at the luminescent center.

In some embodiments the first luminescent center possesses a third energy level separated from the first energy level by an energy difference ΔE_{LC2} and the method comprises coupling the quantum state of the first luminescent center to a photon state in a first resonator having a resonant frequency corresponding to ΔE_{LC2} such that the photon state in the first resonator encodes the first quantum state. In some embodiments the photon state in the first resonator is an optical photon state. In some embodiments the photon state in the first resonator corresponds to an optical wavelength in the range of about 1 μm to about 5 μm.

Some embodiments comprise delivering a photon of the photon state to a second resonator and coupling the second resonator to a second luminescent center such that a quantum state of the second luminescent center encodes the first quantum information.

In some embodiments the photon state in the first resonator is entangled with another photon state in a second resonator and the method comprises coupling the second resonator to a second luminescent center such that a quantum state of the second luminescent center encodes the first quantum information.

Some embodiments comprise encoding the first quantum information in a quantum state of a second matter qubit by coupling the second luminescent center to the second matter qubit by way of another microwave photon state wherein quantum states of the second matter qubit and the second luminescent center engage in a quantum interaction such that the quantum state of the second matter qubit encodes the first quantum information. Some embodiments comprise uncoupling the second matter qubit from the second luminescent center. Some embodiments comprise entangling the photon state with three or more luminescent centers. Some embodiments comprise returning the first quantum information to the first qubit by coupling the first luminescent center to the first qubit by way of another microwave photon state such that quantum states of the first qubit and the first luminescent center engage in a quantum state transfer interaction such that the quantum state of the first qubit encodes the first quantum information.

In some embodiments the first luminescent center comprises a crystal defect in a silicon crystal. In some embodiments the first luminescent center comprises an ensemble of luminescent centers wherein each of the luminescent centers in the ensemble comprises a crystal defect in a silicon crystal.

In some embodiments the crystal defect comprises a T center. In some embodiments the crystal defect has an unpaired ground state spin and comprises an I center or an M center or an Al1 center or a Ga1 center or a Nitrogen-Carbon center or a silicon damage center.

In some embodiments wherein the crystal defect comprises at least one of an electron having an electron spin and a hole having a hole spin and the first and second quantized energy levels of the first luminescent center respectively comprise spin down and spin up states of the electron or hole. In some embodiments the crystal defect comprises at least one nuclear spin and the method further comprises encoding a quantum state of the electron or hole in a quantum state of the nuclear spin such that the nuclear spin encodes the first quantum information.

In some embodiments the crystal defect comprises at least one unpaired electron or hole spin and at least one nuclear spin and the method further comprises encoding the first quantum information in a joint quantum state of the at least one unpaired electron or hole spin and the at least one nuclear spin. In some embodiments encoding the first quantum information in the joint quantum state of the unpaired electron or hole spin and the nuclear spin comprises causing a cross transition. In some embodiments the cross transition comprises an electron dipole spin resonance (EDSR) transition. Some embodiments comprise recovering the first quantum information by setting the unpaired electron or hole spin to have an initialized quantum state and causing a spin transition of the unpaired electron or hole spin and/or the nuclear spin.

In some embodiments the crystal defect comprises a plurality of nuclear spins and the method comprises:

encoding the first quantum information in a first one of the nuclear spins;
causing the first qubit to encode second quantum information;
coupling the first qubit to the first luminescent center by way of a second microwave photon state such that quantum states of the first qubit and an electron or hole of the first luminescent center undergo a quantum interaction and the quantum state of the electron or hole of the first luminescent center encodes the second quantum information;
uncoupling the first qubit from the first luminescent center; and encoding the quantum state of the electron or hole in a quantum state of a second one of the nuclear spins such that the second one of the nuclear spins encodes the second quantum information.

Some embodiments comprise creating a bound exciton by illuminating the crystal defect center with an optical pulse prior to coupling the first qubit to the first luminescent center. Some embodiments comprise encoding the first quantum information in a spin state of the hole. In some embodiments the luminescent center comprises an impurity atom in a silicon crystal.

In some embodiments the impurity atom comprises a double donor atom. In some embodiments the double donor is a selenium, tellurium or sulphur atom.

In some embodiments at least 95% of silicon atoms in the silicon crystal are silicon-28.

In some embodiments the first qubit is in a first refrigerator and the second matter qubit is in a second refrigerator and the first and second resonators are connected by an optical path that passes outside of the first and second refrigerators. In some embodiments at least a portion of the optical path that is outside of the first and second refrigerators is at a temperature that is greater than ΔE_{SQ}/k_{B} where k_{B} is Boltzmann's constant. In some embodiments the optical path comprises an optical fiber. In some embodiments ΔE_{SQ} is 1.3 meV or less.

In some embodiments the first qubit is a superconducting qubit. In some embodiments the first qubit comprises a quantum dot or an ion trap.

Another aspect of the invention provides a method for transferring a quantum state of a superconducting qubit to an optical photon. The method comprises coupling a superconducting qubit having two quantum states having corresponding energy levels separated by an energy ΔE₁ to a luminescent center in silicon having first and second quantum states having corresponding energy levels separated by an energy near ΔE₁ and third and fourth quantum states having corresponding energy levels that are respectively separated from the energy levels corresponding to the first and second states by energies ΔE₂ and ΔE₃ and subsequently coupling the luminescent center to an optical structure that supports a photon mode having a frequency corresponding to the energy ΔE₂ and/or ΔE₃.

In some embodiments ΔE₂≠ΔE₃.

In some embodiments coupling the superconducting qubit to the luminescent center is performed by way of a resonator having a microwave resonant frequency corresponding to the energy ΔE₁.

Some embodiments comprise maintaining the coupling between the superconducting qubit and the luminescent center for a time equal to an odd number of periods of a two qubit Rabi frequency for the coupled superconducting qubit and the luminescent center and then uncoupling the superconducting qubit and the luminescent center.

In some embodiments the optical structure is an optical resonator.

Some embodiments comprise detecting a photon in the optical structure.

Another aspect of the invention provides a method for transferring a quantum state of a superconducting qubit to an optical photon. The method comprises entangling the quantum state of the superconducting qubit with a quantum state of a luminescent center by way of a microwave photon; and subsequently entangling the quantum state of the luminescent center with an optical photon state.

Some embodiments comprise manipulating the quantum state of the luminescent center prior to entangling the quantum state of the luminescent center with the optical photon.

Another aspect of the invention provides a method for storing first quantum information. The method comprises coupling a qubit having a first quantum state with an electron spin or a hole spin in a T center in silicon to transfer the first quantum state to a quantum state of the electron spin or hole spin; and, uncoupling the electron spin or hole spin from the qubit.

Some embodiments comprise subsequently causing a quantum interaction between the quantum state of the electron spin or hole spin with a quantum state of a first nuclear spin of a plurality of nuclear spins of the T center such that some or all of the first quantum information is encoded in the first nuclear spin.

Some embodiments comprise setting the qubit to have a second quantum state and:

coupling the qubit with the electron spin or hole spin in the T center to transfer the second quantum state to the electron spin or hole spin.

Some embodiments comprise uncoupling the electron spin or hole spin from the qubit; and

subsequently transferring the quantum state of the electron spin or hole spin to a quantum state of a second nuclear spin of the plurality of nuclear spins of the T center.

Another aspect of the invention provides an apparatus for storing quantum information. The apparatus comprises: a first qubit having first and second quantized energy levels separated by an energy ΔE_{SQ} corresponding to a microwave frequency; a luminescent center in silicon having first and second quantized energy levels separated by an energy ΔE_{LC1}; and means for coupling the first qubit to the luminescent center by way of a microwave photon.

In some embodiments the first qubit is a superconducting qubit.

In some embodiments the first qubit is a quantum dot or an ion trap.

In some embodiments the means for coupling comprises a microwave resonator.

In some embodiments the means for coupling comprises a means for adjusting one or both of the energy ΔE_{LC1} and the energy ΔE_{SQ} so that ΔE_{LC1} and E_{SQ} are substantially equal.

Some embodiments comprise means for coupling the first qubit to the luminescent center for a time that is substantially equal to n half periods of a two qubit Rabi frequency of the first qubit and the luminescent center wherein n is an odd integer.

In some embodiments the luminescent center comprises a T center.

In some embodiments the luminescent center comprises an ensemble of T centers.

Some embodiments comprise means for selectively coupling an unpaired electron of the T center to a nuclear spin of the T center.

In some embodiments the luminescent center is in a silicon substrate and the first qubit is supported on the silicon substrate.

Another aspect of the invention provides an apparatus for transferring a quantum state of a superconducting qubit to an optical photon. The apparatus comprises: a superconducting qubit having two quantum states having corresponding energy levels separated by an energy ΔE₁; a luminescent center in silicon having first and second quantum states having corresponding energy levels separated by an energy near ΔE₁ and third and fourth quantum states having corresponding energy levels that are respectively separated from the energy levels corresponding to the first and second quantum states by energies ΔE₂ and ΔE₃; means for coupling the superconducting qubit to the luminescent center; and, means for coupling the luminescent center to an optical structure that supports a photon mode having a frequency corresponding to the energy ΔE₂ and/or ΔE₃.

Another aspect of the invention provides a method for creating quantum entanglement among a plurality of spaced-apart qubits. Each of the qubits have first and second quantized energy levels separated by an energy ΔE_{SQ} corresponding to a microwave frequency. The method comprises coupling each of the qubits to a corresponding luminescent center in silicon by way of microwave photon states, the luminescent center having at least first, second and third quantized energy levels wherein the first and second energy levels are separated by an energy difference corresponding to an energy of the microwave photon states and the first and third energy levels are separated by an energy difference corresponding to an energy of optical photons; and, coupling each of the luminescent centers to the other ones of the corresponding luminescent centers by way of an optical structure that supports one or more optical photon states having energies corresponding to a quantum transition of the luminescent center between the first and third energy levels.

Another aspect of the invention provides a method for quantum computing. The method comprises: storing quantum information as a qubit state in a defect in a silicon crystal wherein the defect comprises a plurality of impurity atoms that collectively include at least one unpaired electron having a corresponding electron spin state and a plurality of nuclear spins each having a corresponding nuclear spin state; and setting one of the spin states to represent the qubit information and using a plurality of the nuclear spins for quantum error correction or error detection for the qubit information.

Some embodiments comprise using the plurality of nuclear spins for majority voting local error correction.

Some embodiments comprise using the plurality of nuclear spins as ancillas for encoding the qubit information in a logical qubit.

In some embodiments the defect comprises a T center, an I center or an M center.

In some embodiments the defect comprises a T center.

In some embodiments energy levels of transitions between different nuclear spin states of the nuclear spins are different for different ones of the nuclear spins.

Another aspect of the invention provides a method for quantum entanglement purification. The method comprises: providing first and second defects in a silicon crystal wherein the first and second defects each comprise an operational qubit comprising an electron or hole spin and at least one memory qubit comprising a nuclear spin; and entangling quantum states of the operational qubits of the first and second defects; transferring the entanglement to the at least one memory qubit of each of the first and second defects by state transfer.

Some embodiments comprise repeating the steps of: entangling quantum states of the operational qubits of the first and second defects; and transferring the entanglement to the at least one memory qubit of each of the first and second defects by state transfer.

In some embodiments the defect comprises a T center, an I center or an M center. In some embodiments the defect comprises a T center.

Another aspect of the invention provides a method for storing quantum information in a defect in a silicon crystal. The method comprises: setting a quantum state of an electron or hole spin of the defect to encode first quantum information and initializing a first nuclear spin of the defect to a first initial nuclear spin state; and illuminating the defect with first photons that have a first wavelength matching the energy of a first spin transition that involves the electron or hole spin and the first nuclear spin.

Some embodiments comprise setting a quantum state of the electron or hole spin of the defect to encode second quantum information and initializing a second nuclear spin of the defect to a second initial nuclear spin state; and illuminating the defect with second photons that have a second wavelength matching the energy of a second spin transition that involves the electron or hole spin and the second nuclear spin.

In some embodiments the first transition is a cross transition.

In some embodiments the first photons are provided in the form of a coherent pi pulse.

In some embodiments the defect comprises a T center, an I center or an M center.

In some embodiments the defect comprises a T center.

Further aspects and example embodiments are illustrated in the accompanying drawings and/or described in the following description.

It is emphasized that the invention relates to all combinations of the above features, even if these are recited in different claims.

### BRIEF DESCRIPTION OF THE DRAWINGS

The accompanying drawings illustrate non-limiting example embodiments of the invention.

FIG. 1 illustrates schematically a system that includes a short lived qubit and apparatus for extending a lifetime of the short lived qubit.

FIG. 1A schematically illustrates energies of quantum states of a short lived qubit and a long lived qubit and the interactions of photons with the short lived and long lived qubits.

FIG. 2 is a graph illustrating the evolution of probability densities for two coupled quantum systems.

FIG. 3 is a flow chart illustrating an example method for preserving a quantum state of a short lived qubit.

FIG. 4 is a schematic illustration showing a construction for an example system that includes a short lived qubit and a long lived qubit.

FIG. 5 is a schematic illustration showing a qubit that that couples to both microwave and optical photons arranged to couple quantum information to an external system.

FIG. 6 is an example energy level diagram for quantum states in a qubit that may couple to both microwave and optical photons.

FIG. 6A is a schematic view showing long lived qubits located to couple to microwave photons by electric field or magnetic field interactions.

FIG. 6B is a schematic view showing energy levels for a quantum system that can include a bound exciton in which a hole spin state can serve as a long lived qubit.

FIGS. 7A and 7B are respectively cross section and plan views that schematically illustrate a system in which a qubit is arranged for coupling to optical photons.

FIG. 8 is a schematic view showing a system in which qubits in plural refrigerators can be coupled by optical photons.

FIG. 9 shows the structure of a T center in silicon.

### DETAILED DESCRIPTION

Throughout the following description, specific details are set forth in order to provide a more thorough understanding of the invention. However, the invention may be practiced without these particulars. In other instances, well known elements have not been shown or described in detail to avoid unnecessarily obscuring the invention. Accordingly, the specification and drawings are to be regarded in an illustrative, rather than a restrictive sense.

One aspect of this invention provides apparatuses which extend lifetimes of qubits. The qubits may, for example comprise superconducting qubits. One disadvantage of superconducting qubits is that their lifetime is undesirably short (usually with coherence times on the order of 100 μs or shorter). This interferes with the ability to process quantum information using superconducting qubits.

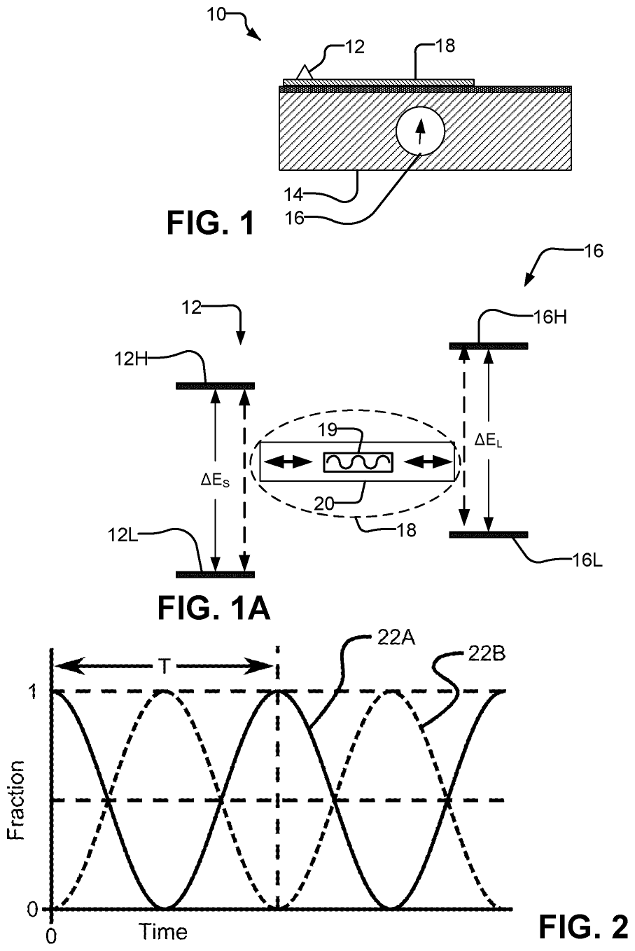

FIG. 1 illustrates schematically a system 10 that includes a short lived qubit 12. Short lived qubit 12 may, for example comprise a superconducting qubit such as a transmon or other charge-based or flux-based superconducting qubit.

System 10 takes advantage of the fact that qubits provided in a silicon crystal can have lifetimes several orders of magnitude longer than short lived qubits such as superconducting qubits. System 10 includes a body 14 made of silicon. Preferably but optionally body 14 comprises the purified isotope of silicon that has an atomic weight of 28 (“silicon 28”). Body 14 may, for example, be a part of a substrate on which short lived qubit 12 is formed. Body 14 includes at least one long lived qubit 16.

Long lived qubit 16 may, for example comprise an unpaired spin (e.g. an electron spin or a nuclear spin or a hole spin in an exciton) or a number of excitons. An exciton may, for example, be created by illuminating a luminescent center with optical radiation having a frequency corresponding to an energy of the exciton.

Long lived qubit 16 may be provided by one or more particles or quasi particles in a luminescent center. In some embodiments a luminescent center is provided by a crystal defect in body 14 such as a color center that has an unpaired ground state spin (e.g. a T center, an I center, or an M center, an Al1 center or a Ga1 center, or a Nitrogen-Carbon centre, or a spin-active silicon radiation damage center or a silicon color center with an unpaired ground state spin). Where the luminescent center is a crystal defect the particles or quasi particles may, for example, be electrons, holes, atomic nuclei, or excitons of the luminescent center. Some types of crystal defects provide plural particles or quasi particles that may be used individually or in groups to provide long lived qubits. For example, a T centre has at least three nuclear spins, an electron spin, a possibility of a hole spin in a bound exciton and an exciton number which may all be used as long lived qubits 16.

In some cases a crystal defect may include one or more impurity atoms. In some embodiments a luminescent center is provided by an impurity atom in which case long lived qubit 16 may be provided by one or both of an electron spin and a nuclear spin of the impurity atom.

In some embodiments long lived qubit 16 comprises an unpaired spin provided by an atom of an impurity such as selenium or sulphur or tellurium in a silicon crystal.

System 10 also includes a controllable coupling 18. Coupling between short lived qubit 12 and long lived qubit 16 by way of coupling 18 can be controlled to selectively allow short lived qubit 14 and long lived qubit 16 to interact with one another.

Coupling 18 is configured to permit sufficiently strong coupling between short lived qubit 12 and long lived qubit 16 to facilitate state-transfer between or entanglement of short lived qubit 12 and long lived qubit 16. The coupling may, for example, comprise a resonator designed to accommodate photons having energies corresponding to quantum transitions of short lived qubit 12 and long lived qubit 16.

One measure of the strength of coupling between short lived qubit 12 and long lived qubit 16 is the two-qubit Rabi frequency which is described elsewhere herein. The two qubit Rabi frequency increases as the coupling between the two qubits becomes stronger. To facilitate efficient quantum interaction between short lived qubit 12 and long lived qubit 16 the period of the Rabi frequency should be larger than the coherence times of short lived qubit 12 and long lived qubit 16. For example, one can define “cooperativity” as follows:

$$C = \frac{{f}_{R}^{2}}{{R}_{SL} * {R}_{LL}}$$

where C is the cooperativity, f_{R} is the Rabi frequency, R_{SL} is the decoherence rate (i.e. the inverse of the decoherence time) for the short lived qubit and R_{LL} is the decoherence rate for the long lived qubit. In some embodiments the strength of the coupling is given by a cooperation value C≥1 when coupling 18 is coupling short lived qubit 12 to long lived qubit 16.

In some embodiments C>1 is achieved with a two-qubit Rabi frequency of less than 50 kHz. For example, where short lived qubit 12 has a coherence time of 1 μs (which is typical for some superconducting qubits) and long lived qubit 16 has a coherence time of 1 ms (which is typical for an electron spin in a T center) then C>1 can be achieved with a two qubit Rabi frequency of 30 kHz or more. As another example, where short lived qubit 12 has a coherence time of 1 μs and long lived qubit has a coherence time on the order of 1s (which is typical for a nuclear spin in a T center in silicon) a two qubit Rabi frequency of 1 kHz or more is sufficient to achieve C>1.

The Rabi frequency may be increased by increasing the strength of coupling between short lived qubit 12 and long lived qubit 16. This may be achieved, for example by one or more of:
making transition energies of short lived qubit 12 and long lived qubit 16 match more closely;
making short lived qubit 12 and long lived qubit 16 physically closer to one another;
more closely matching a resonant frequency of a coupling 18 (e.g. a resonator) to the transition energies of short lived qubit 12 and long lived qubit 16;
providing a geometry in which short lived qubit 12 and long lived qubit 16 can each couple to antinodes of electromagnetic modes that couple short lived qubit 12 and long lived qubit 16.

Short lived qubit 12 may represent qubit values in various ways, for example, constructions of superconducting qubits in which quantum information is stored by phase, charge or flux are all known.

In some embodiments, coupling 18 comprises a resonator arranged so that a maximum of an electromagnetic field associated with a short lived qubit 12 couples to the resonator. For example, where short lived qubit 12 is a superconducting flux qubit, the resonator may be inductively coupled to a magnetic field antinode of the superconducting flux qubit. As another example, where short lived qubit 12 is a superconducting charge qubit or a superconducting phase qubit the resonator may be capacitively coupled at an electric field antinode of short lived qubit 12.

A resonator of coupling 18 may be arranged so that an electromagnetic field maximum of a photonic mode supported by the resonator is located at or close to the location of long lived qubit 16.

In some embodiments coupling 18 is provided by a direct interaction of an electromagnetic field of short lived qubit 12 with long lived qubit 16. In such embodiments, coupling 18 is provided by the relative physical arrangement of short lived qubit 12 relative to long lived qubit 16 which allows them to be coupled for quantum interaction as described herein. Long lived qubit 16 may be located at or near to a point at which the electromagnetic field associated with short lived qubit 12 has a maximum. For example, where short lived qubit 12 comprises a superconducting flux qubit comprising a flux loop, a long lived qubit 16 (e.g. a T centre) may be located inside the flux loop where it can couple directly to a magnetic field produced by the flux loop. Where short lived qubit 12 is a charge or phase qubit, long lived qubit 16 may be located at or close to an electric field maximum of the electric field produced by the short lived qubit 12. In some embodiments, long lived qubit 16 is at a location where the electromagnetic field of short life qubit 12 with which long life qubit 16 interacts has a strength that is no more than 3 dB lower or 2 dB lower than a strength of the electromagnetic field at a location where the electromagnetic field has maximum strength.

In some embodiments the energy difference between quantum states of each of short lived qubit 12 and long lived qubit 16 correspond to photon frequencies in the radiofrequency (RF) or microwave region. For example, in some embodiments photon frequencies are in the range of about 1 MHz to 100 GHz. In some embodiments the photon frequencies are in the range of 1 GHz to 100 GHz. In some embodiments the photon frequencies are in the range of 3 GHz to 8 GHz.

The relationship between energy and photon frequency is given by the relationship:

E=hw

Where E is the energy difference, h is Planck's constant and v is the photon frequency. Photon frequency is related to photon wavelength by:

υ=c/λ

Where c is the speed of light and λ is the photon wavelength.

System 10 may comprise a mechanism operative to cause the energy difference ΔE_{S} between quantum states in short lived qubit 12 and the energy difference ΔE_{L} between quantum states in long lived qubit 16 to be equal or close to equal. Those of skill in the art will understand that short lived qubit 12 and long lived qubit 16 can engage in quantum interactions (e.g. state transfer or quantum entangling operations) even if there are small differences between ΔE_{S} and ΔE_{L}. For convenience, in this disclosure when two energies are stated to be “equal” (e.g. as in ΔE_{S}=ΔE_{L}) what is meant is that the two energies are exactly equal or close enough to being equal for the described purpose (e.g. entanglement of two quantum systems). Similarly, when two frequencies are said to be equal or to match (e.g. a resonant frequency of a resonator and a frequency of a photon) what is meant that the two frequencies are exactly equal or close enough to being equal for the desired purpose (e.g. excitation of a photon mode in the resonator).

How closely ΔE_{S} and ΔE_{L} need to be made to be equal to one another to achieve desired quantum interactions will depend on factors such as the strength of coupling between short lived qubit 12 and long lived qubit 16 and linewidths of the quantized transitions of short lived qubit 12 and long lived qubit 16. In some embodiments the energy difference ΔE_{S} between quantum states in short lived qubit 12 and the energy difference ΔE_{L} between quantum states in long lived qubit 16 are made to be equal within 1% or ½% or 1 part in 10000.

In some embodiments ΔE_{S} and ΔE_{L} are non-equal unless one or both are controlled to achieve ΔE_{S}=ΔE_{L}. Such a mechanism may adjust one or both of ΔE_{S} and ΔE_{L} for example by applying magnetic, electric, or RF control fields to short lived qubit 12 and/or long lived qubit 16 and/or by applying strain to a substrate in which long lived qubit 16 is located.

System 10 optionally also includes a mechanism for adjusting the coupling between short lived qubit 12 and long lived qubit 16. This mechanism may, for example comprise an adjustable resonator that has a resonant frequency that is adjustable to either match or not match the frequency of photons having energies equal to ΔE_{S} and ΔE_{L}.

When ΔE_{S}≠ΔE_{L} and/or the coupling between short lived qubit 12 and long lived qubit 16 is disabled in some other manner then quantum states of short lived qubit 12 and long lived qubit 16 can evolve essentially independently of one another.

When ΔE_{S}=ΔE_{L} and the coupling between short lived qubit 12 and long lived qubit 16 is sufficient the quantum states of short lived qubit 12 and long lived qubit 16 may become entangled by way of microwave photons. This is illustrated in FIG. 1A.

FIG. 1A shows schematically states 12H and 12L of short lived qubit 12 and states 16H and 16L of long lived qubit 16. Short lived qubit 12 can emit a photon 19 and transition from state 12H to 12L. Short lived qubit 12 can absorb a photon 19 and transition from state 12L to 12H. Long lived qubit 16 can emit a photon 19 and transition from state 16H to 16L. Long lived qubit 16 can absorb a photon 19 and transition from state 16L to 16H.

Because qubits 12 and 16 are quantum systems, in the absence of a quantum measurement, a larger system including qubit 12, qubit 16 and photons 19 can exist in a superposition of states which may include states in which either or both of qubits 12 and 16 has emitted a photon 19 and states in which either or both of qubits 12 and 16 has absorbed a photon 19. The states of qubits 12 and 16 are entangled with one another and with the states of photons 19 by which their quantum states are coupled.

Coherent coupling of short lived qubit 12 and long lived qubit 16 may be selectively enabled, for example to entangle quantum states of short lived qubit 12 and long lived qubit 16 and/or to transfer a quantum state of short lived qubit 12 to long lived qubit 16 and/or to transfer a quantum state of long lived qubit 16 to short lived qubit 12, by adjusting one or more of:
ΔE_{S};
ΔE_{L} and
the coupling between qubits 12 and 16.

In some embodiments, coupling between short lived qubit 12 and long lived qubit 16 is facilitated by a resonator 20 that has a resonant frequency corresponding to the frequency of microwave photons 19 that are emitted/absorbed when short lived qubit 12 and long lived qubit 16 transition between quantum states. Resonator 20 may, for example comprise a patch of superconducting material in a circuit designed to have a resonant frequency corresponding to photons 19. Resonator 20 may, for example, comprise a coplanar waveguide resonator or an LC resonator.

Resonator 20 may be positioned close enough to each of qubits 12 and 16 to provide a sufficient level of coupling between each of qubits 12, 16 and photons 19 in resonator 20. Capacitive or inductive coupling between a superconducting qubit 12 and resonator 20 can have a relatively long range such that a spacing between such a qubit 12 and a resonator 20 can be e.g. ≥a few μm. As another example, coupling between a quantum dot used as qubit 12 and resonator 20 typically has a much shorter range such that resonator 20 is best located closer than about 1 μm or closer than 100 nm to the quantum dot. Coupling between resonator 20 and a long lived qubit 16 may have a range of a few microns in which case resonator 20 may be located within a few μm of the long lived qubit 16.

A mechanism may be provided for adjusting the energy gap between quantum states of a qubit. The nature and construction of the mechanism will depend on the nature of the quantum system on which the qubit is based. For example:
Where the qubit is provided by an electron spin or a hole spin or a nuclear spin in a magnetic field the energy difference between spin up and spin down states may be adjusted by changing a strength of the magnetic field at the location of the electron or nucleus.
Where the qubit is a superconducting qubit the energy difference between states may be adjusted by adjusting the quantized magnetic flux through a superconducting circuit that implements the superconducting qubit. This may be done, for example, by altering a capacitance or inductance of the superconducting circuit.
Where the qubit is provided by an atom or defect in a crystal lattice then energy levels of the qubit may be altered by applying strain to the crystal lattice.
Where the qubit is provided by an electron spin or a hole spin or a nuclear spin in a magnetic field the energy levels of the qubit may be adjusted by applying an RF driving field to the qubit. The frequency of the RF driving field may, for example be set to be in a range such that the energy of photons of the RF driving field is at least approximately equal (e.g. within about 1% or ½% or one part in 10000) to the energy difference between the energy levels of the qubit. The energy levels of the qubit may be varied by adjusting the frequency of the RF driving field and/or the amplitude of the RF driving field.
Where the qubit is provided by an electron spin or a hole spin or a nuclear spin in a magnetic field the energy levels of the qubit may be adjusted by applying an electric field at the location of the qubit. In some embodiments the electric field is oriented to be parallel to an orientation of the magnetic field

When short lived qubit 12 and long lived qubit 16 are coupled by coupler 18 as described above, energy can be transferred back and forth between short lived qubit 12 and long lived qubit 16 by way of photons 19. The possibility for such energy transfer results in an oscillation of a probability density function which indicates the probability of finding short lived qubit 12 in a particular quantum state (e.g. 12H or 12L). This oscillation occurs at the so-called two-qubit Rabi frequency which depends on the coupling between short lived qubit 12 and long lived qubit 16.

The Rabi frequency can be determined in advance. The two-qubit Rabi frequency may be measured in a calibration step. The calibration step may, for example, comprise initializing long lived qubit 16 and short lived qubit 12 into known quantum states, turning on the coupling for some time ‘tau’, turning off the coupling, and then independently measuring both of qubits 12 and 16. By repeating this measurement sequence for different values of tau one can obtain a plot like that shown in FIG. 2 from which the Rabi frequency can be readily determined. The Rabi frequency determined by the calibration step may be stored in a data store for future use. For example, the data store may comprise a memory location accessible to a control circuit connected to control the coupling between long lived qubit 16 and short lived qubit 12 using any of the mechanisms described herein.

FIG. 2 is a graph showing the probability density for short lived qubit 12 being in the higher-energy level of two non-degenerate binary quantum states (curve 22A) and the probability for long lived qubit 16 being in the higher-energy level one of two non-degenerate binary quantum states (curve 22B).

In FIG. 2, at time 0 short lived qubit 12 is in its higher-energy quantum state and long lived qubit 16 is in its lower-energy quantum state. This may be caused by making a quantum measurement at time 0 or by manipulating the states of qubits 12, 16. At time 0, system 10 is configured to couple the states of short lived qubit 12 and long lived qubit 16.

The probability density represented by curve 22A cycles with a period T. At time T/2 long lived qubit 16 has a high probability of being in its higher energy state and short lived qubit 12 has a low probability of being in its lower-energy quantum state. In essence, the quantum state of short lived qubit 12 has been transferred to long lived qubit 16 and vice versa.

The principle illustrated in FIG. 2 also applies to other quantum states of short lived qubit 12 and long lived qubit 16 and their superpositions.

As described above, a state of short lived qubit 12 (which may be a superconducting qubit) can be transferred to a long lived qubit 16 (which may be a spin qubit for example), stored in long lived qubit 16 for a period of time that is longer than the lifetime of short like qubit 12, and then returned to short lived qubit 12 for further processing.

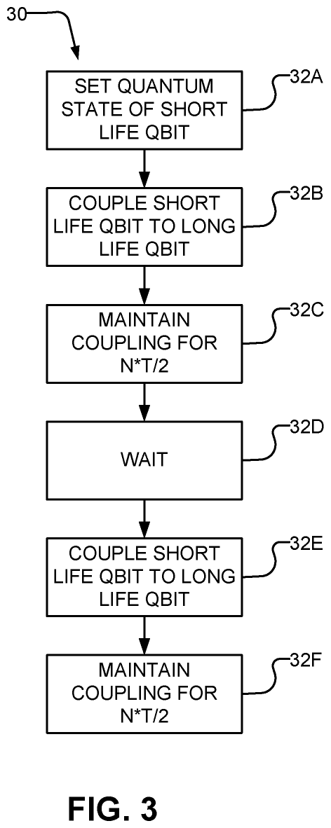

FIG. 3 illustrates a method 30 for extending the lifetime of a quantum state of short lived qubit 12. In block 32A short lived qubit 12 is placed into a desired quantum state. The quantum state may be a superposition of a higher-energy state and a lower-energy state. Block 32A may, for example, comprise performing a quantum computation in a quantum computer of which short lived qubit is a part.

In block 32B, short lived qubit is coupled to long lived qubit 16, for example by a coupler 18 as described above. Block 32B may, for example, comprise adjusting an energy difference ΔE_{L} between the higher-energy and lower energy quantum states of long lived qubit 16 and/or adjusting an energy difference ΔE_{S} between the higher-energy and lower energy quantum states of short lived qubit 12 to achieve ΔE_{S}=ΔE_{L}.

In block 32C, the coupling between short lived qubit 12 and long lived qubit 16 is maintained for a time τ equal to an odd number, N (N=1, 3, 5, . . . ) of half periods T/2 of the Rabi period (e.g. one half period) and then discontinued (e.g. coupling may be discontinued by adjusting one or both of ΔE_{S} and ΔE_{L}. so that ΔE_{S}≠ΔE_{L} and/or by changing a resonant frequency of a resonator 20). Time τ is significantly shorter than the decoherence time of short lived qubit 12.

The time for maintaining the coupling between short lived qubit 12 and long lived qubit 6 may be controlled by a timer that uses a stored value equal to or derived from the two-qubit Rabi frequency for the particular pair of short lived qubit 12 and long lived qubit 16 determined in a calibration step to set the time for which the coupling is maintained.

At the end of block 32C the desired quantum state of short lived qubit 12 has been transferred to long lived qubit 16.

In block 32D a time period passes. The time period may have a length that is longer than a decoherence time of short lived qubit 12. The time period has a length that is shorter than a decoherence time of long lived qubit 16. In some embodiments the time period has a length of more than 10 μs or more than 100 μs or more than 1 s or more than 1 minute.

In block 32E short lived qubit 12 is once again coupled to long lived qubit 16, for example by a coupler 18 as described above. Block 32E may operate in the same manner described herein for block 32B, for example.

In block 32F the coupling between short lived qubit 12 and long lived qubit 16 is maintained for an odd number (N=1, 3, 5, . . . ) of half periods T/2 of the Rabi period and then discontinued. Block 32F may be performed as described above for block 32C, for example.

At the end of block 32F short lived qubit 12 has been restored to the desired quantum state.

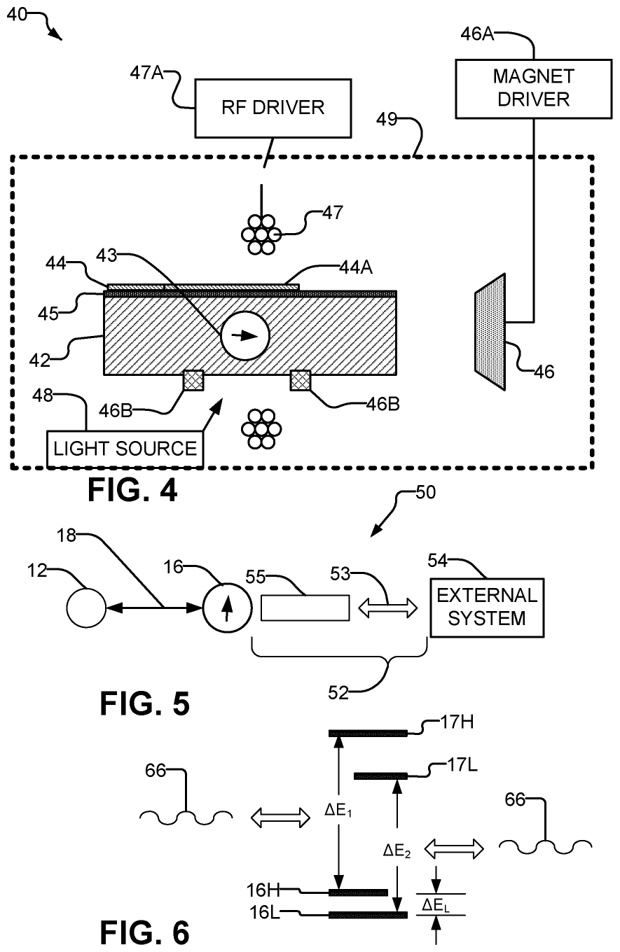

FIG. 4 shows a possible simplified physical structure for a system 40 that provides a short lived qubit 12 and a long lived qubit 16 which can be selectively coupled and uncoupled to perform method 30 or other similar methods. System 40 includes a silicon substrate 42. Substrate 42 is preferably purified silicon 28 (i.e. silicon that is more than 92.23% silicon 28). In some embodiment the material of substrate 42 is at least 96% or 99% or 99.5% or 99.9% (by number of atoms) silicon 28.

Long lived qubit 16 may be provided by a luminescent center 43 in substrate 42. For example, the luminescent center may comprise a luminescent center selected from: a defect such as a T center, an I center, or an M center, or a Nitrogen-Carbon center, or an Al1 or a Ga1 center, or a radiation damage center with an unpaired ground state spin; or an impurity such as an atom of selenium or tellurium or sulphur or other double donor impurity.

Short lived qubit 12 may be provided by a superconducting structure 44 that is supported on substrate 42. Structure 44 may comprise a patterned layer of a metal that is superconducting at low temperatures that has been deposited on substrate 42. The layer may, for example comprise a superconducting loop that includes a Josephson junction. An electrically insulating layer 45 may be present between superconducting structure 44 and the body of substrate 42 in which luminescent center 43 is located.

A coupler (that performs the role described above for coupler 18) may be provided by a part 44A of superconducting structure 44 that is designed to provide a resonance at a frequency corresponding to an energy to which both of energy differences ΔE_{S} and ΔE_{L} can be made to equal. Part 44A may for example, comprise a tab of superconducting material that is in a circuit that has a resonant frequency in the microwave range. Part 44A may physically overlie luminescent center 43.

Luminescent center 43 should be spaced closely enough to part 44A to couple to electric or magnetic field components of photons in part 44A. To couple to electric fields, a luminescent center 43 should have a non-negligible capacitance with part 44A. In some embodiments, luminance center 43 is spaced apart from part 44A by a distance on the order of about 1 μm or less or a distance on the order of 100 nm or less. Preferably part 44A is aligned relative to crystallographic axes of substrate 42 so that the electric or magnetic field of the photon mode in part 44A couples well to luminescent center 43. In some embodiments the magnetic field of the photon mode is non-parallel (e.g. orthogonal) to an external magnetic field applied to luminescent center 43.

FIG. 4 also shows an adjustable magnet 46 that is operable to change a magnitude of a magnetic field at the location of luminescent center 43 (and to therefore change a difference in energies between spin up and spin down states of a spin such as an electron spin used to provide long lived qubit 16). A control circuit 46A is connected to control adjustable magnet 46 (for example to turn on and off coupling between long lived qubit 16 and short lived qubit 16). One or more permanent magnets 46B in the vicinity of luminescent center 43 may augment the magnetic field from adjustable magnet 46. Magnets 46B may be deposited on or in or near substrate 42.

It is generally beneficial to minimize the component of the magnetic field produced by magnets 46 and 46B that is transverse to a plane of superconducting structure 44. This is because the critical magnetic field for thin film superconductors (i.e. the magnetic field strength above which the superconductor stops being superconductive) is typically much lower for transverse (perpendicular) magnetic fields than for fields in which field lines are parallel to superconducting structure 44.

FIG. 4 also shows coils 47 that may be driven by an RF signal source 47A to manipulate a quantum state of long lived qubit 16 by a resonance effect (e.g. electron spin resonance—“ESR”) as is known to those of skill in the art. RF signal source may be controlled to produce pulses of radiation such as pi pulses or pi/2 pulses which, when delivered, manipulate the quantum state of long life qubit 16.

FIG. 4 also shows an optional light source 48 arranged to illuminate a location of long lived qubit 16. Light source 48 may, for example, emit light having a wavelength that corresponds to an optical transition of long lived qubit 16, for example creation of an exciton. For example, long lived qubit 16 may comprise an exciton in a crystalline defect such as a T center. Light source 48 may be operated to create the exciton by issuing a pulse of light of the appropriate wavelength. Quantum information may then be stored in the exciton, for example in a spin state of the exciton. Light source 48 may, for example, comprise a laser. The laser may be tunable to emit light having wavelengths corresponding to different optical transitions of long life qubit 16.

Substrate 42 is contained within a refrigerator 49 capable of reaching cryogenic temperatures at which structure 44 is superconducting. In some embodiments the operating temperature of structure 44 may be very low (e.g. a few mK or a few Kelvins).

In addition to or as an alternative to storing quantum information, a system as described herein may be used as a pathway for transferring quantum information to or from a quantum information processing system of which short lived qubit 12 is a part and/or as a mechanism for generating optical photons which represent a quantum state of short lived qubit 12.

FIG. 5 schematically illustrates apparatus 50 according to an example embodiment in which a quantum communication pathway 52 connects long lived qubit 16 to an external system 54.

Quantum information pathway 52 may, for example, carry quantum information in the form of optical photons. Quantum information pathway 52 may, for example comprise a waveguide 53 which can carry photons that carry quantum information. In some advantageous embodiments the optical photons have wavelengths in the range of about 1.3 to about 1.7 μm or about 1 μm to about 3 μm.

Quantum information pathway 52 may be coupled to long lived qubit 16 by way of an optical resonator 55 that is located in proximity to long lived qubit 16. To facilitate coupling of long lived qubit 16 to optical photons in optical resonator 55, long lived qubit 16 should have available quantum states that have energy levels that can be separated by an energy difference that corresponds to an energy of optical photons In this case long lived qubit 16 can undergo allowable transitions in which it emits or absorbs optical photons

In some cases the photons that can be emitted or absorbed in different allowable transitions of long lived qubit 16 have different polarizations. In such cases the polarization of emitted photons may encode a quantum state of the long lived qubit 16 from which the photons are emitted. In some cases long lived qubit 16 becomes entangled with photons that have a certain polarization state and as a result, quantum information that was represented by the spin state of qubit 16 can be accessed via the polarization state of the entangled photons.

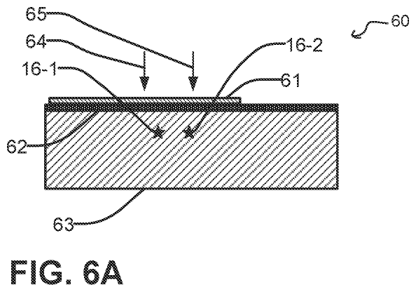

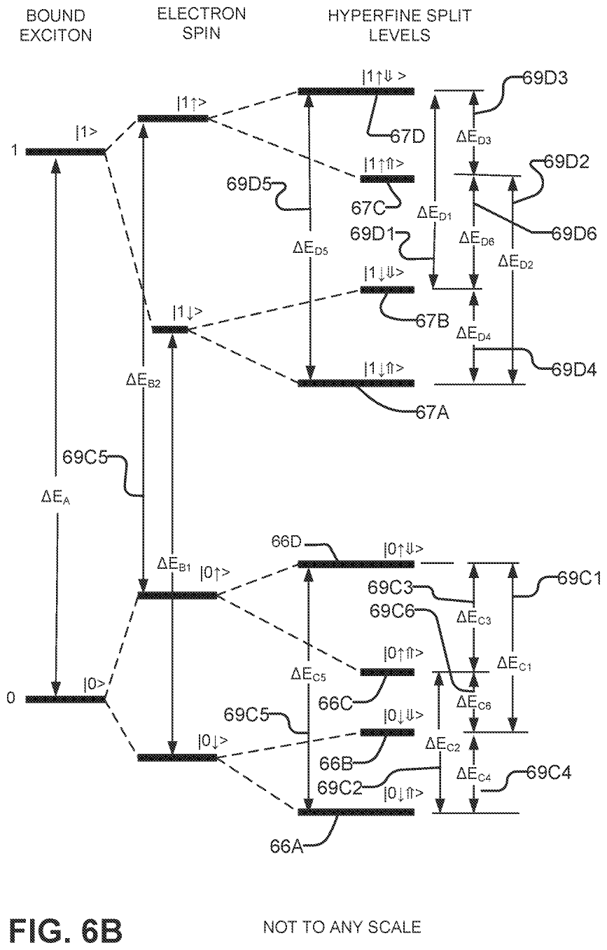

FIG. 6 shows a simplified example structure of energy levels for long lived qubit 16. Levels 16H and 16L may, for example, correspond to spin up and spin down states of an unpaired spin (e.g. or an electron or a hole), for example levels 16H and 16L may be the result of hyperfine splitting caused by interactions between nuclear and electronic spins at the location of long lived qubit 16. The energy difference between levels 16H and 16L may correspond to the energy of photons at microwave wavelengths.

Long lived qubit 16 also has states 17H and 17L that may correspond respectively to spin up and spin down states of an unpaired spin (e.g. of an electron or a hole). States 17H and 17L may be related respectively to states 16H and 16L by an orbital or an excitonic transition. The energy differences between states 17H and 16H or between states 17L and 16L may correspond to the energy of photons at optical wavelengths.

As shown in FIG. 6 the energy difference ΔE1 between states 16H and 17H is different from the energy difference ΔE2 between states 16L and 17L. In some embodiments the difference between ΔE1 and ΔE2 corresponds to a frequency difference of at least about 1 MHz. (i.e. about 6.6×10⁻²⁸ J). This creates an opportunity to provide optical photons that probably will or probably will not interact with long lived qubit 16 depending on whether the unpaired spin is spin up or spin down.

For example, when optical photons 66 which have a wavelength corresponding to an energy that is equal to ΔE1 are provided, long lived qubit 16 may absorb one of the photons 66 and transition from state 16H to state 17H. Long lived qubit 16 may subsequently transition from state 17H to 16H and emit a photon 66 having the same energy ΔE1.

Since, however, long lived qubit 16 is a quantum system, long lived qubit 16 is not necessarily in a definite quantum state. Instead long lived qubit may be in a superposition of states. Also, long lived qubit 16 and optical photons 66 may together be in a superposition of states in which long lived qubit 16 has or has not interacted with a photon. In general, the quantum state of the quantum system made up of long lived qubit 16 and optical photons 66 encompasses a wide variety of possible interactions between long lived qubit 16 and optical photons 66. Consequently the quantum states of long lived qubit 16 and optical photons 66 can be entangled.

It can be seen that energy structures such as those illustrated in FIG. 6 can be used to couple a long lived qubit 16 to other quantum objects by either of microwave photons and optical photons. This property may be exploited to store quantum information in long lived qubit 16 from a selected one of plural sources and/or to transfer quantum information from long lived qubit 16 to a selected one or more of plural destinations. This property may be exploited to transform quantum information from a microwave photon to an optical photon by way of long lived qubit 16 and/or to transform quantum information from an optical photon to a microwave photon by way of long lived qubit 16.

Long lived qubit 16 may be coupled to microwave photons and/or a short lived qubit 12 by various mechanisms. These include:
coupling via an electrical field; and
coupling via a magnetic field; Some embodiments have physical constructions which optimize one or more of these coupling mechanisms.

In some embodiments the coupling promotes electron dipole spin resonance (“EDSR”) interactions.

Long lived qubit 16 may couple to an electric field component of a microwave photon. To optimize electrical coupling the microwave photon may be present as a standing wave mode in a resonator wherein the standing wave mode has one or more antinodes of maximum electric field strength. Long lived qubit 16 may be located in close proximity to an antinode of maximum electric field strength (e.g. within a few μm of the antinode).

In apparatus 60 according to an example embodiment illustrated in FIG. 6A microwave photons may be present in a metallic resonator structure 61 on a silicon layer 63. An electrically insulating layer 62, for example, a layer of silicon dioxide, separates resonator structure 61 from layer 63. Microwave photons in resonator structure 61 have a standing wave mode in which an electric field strength is greatest at an antinode 64. Long lived qubit 16-1 is located in or on silicon substrate 63 proximate to node 64.

Electric field interactions have a long enough range that in some embodiments a long lived qubit couples to the electric field of a photon that is not in a resonant cavity (e.g a photon in an optical waveguide that is proximate to the long lived qubit 16).

Long lived qubit 16 may couple to a magnetic field component of a microwave photon. To optimize electromagnetic coupling the microwave photon may be present as a standing wave mode in a resonator wherein the standing wave mode has one or more antinodes of maximum magnetic field strength and/or one of more antinodes of maximum electric field strength. For example, long lived qubit 16 may be located in close proximity to (e.g. within a few μm of) an antinode of maximum magnetic field strength. For example, FIG. 6A shows a long lived qubit 16-2 located in or on silicon substrate 63 in close proximity to an antinode 65 at which magnetic field strength for the standing wave mode is maximized.

In some embodiments resonator structure 61 comprises a coplanar waveguide (“CPW”) resonator. A CPW resonator may comprise a coplanar waveguide with a signal pin segmented into a stub that is capacitively coupled to signal feedlines. A CPW resonator can support standing wave resonance at a frequency that depends on the length of the stub. Electric field antinodes are located at ends of the stub.

In some embodiments, resonator structure 61 has a high quality factor (“Q factor”). The Q factor is the ratio of the center frequency of the resonator to the bandwidth of the resonator. In some embodiments resonator structure 61 has a Q factor of at least 10⁵ or at least 10⁶.

The notation |↓ [symbol] indicates a quantum state where an electron (or hole) represented by a first arrow is spin down and a nucleus represented by a second arrow is spin up.

Spin transitions can occur in a system in which a bound exciton may be created. The quantum number 0 may indicate no bound excitons and the quantum number 1 may indicate that one bound exciton is present. In notation indicating the quantum state of a system that can include an exciton state, an electron (or hole) spin state and a nuclear spin state the exciton quantum number may be followed by the electron (hole) spin followed by the nuclear spin. For example the notation |1↓ [symbol] indicates a quantum state in which there is one bound exciton, a hole is spin down and a nuclear spin is spin up. This notation is used in the right hand column of FIG. 6B.

In the system illustrated in FIG. 6B a bound exciton may be created when a photon having energy ΔE_{A} is absorbed. In a T center ΔE_{A} corresponds to a photon wavelength of about 1326 nm. A bound exciton may be created by directing light having this wavelength at a T center. When a bound exciton is present the system of upper energy levels 67A, 67B, 67C, 67D shown on the right side of FIG. 6B is available. When a bound exciton is not present, only the lower energy levels 66A, 66B, 66C, 66D are available. It is possible for a T center to be in a supersposition of states including a state in which a bound exciton is present and another state in which the bound exciton is not present.

Transitions are possible between any of the energy levels on the right hand side of FIG. 6B. These transitions can be categorized as:
transitions which flip an electron or hole spin but not a nuclear spin (e.g. electron paramagnetic resonance (EPR) transitions). Transitions 69C1, 69C2, 69D1 and 69D2 are examples of transitions in which only an electron or hole spin flips;
transitions which flip a nuclear spin but not an electron spin (e.g. nuclear magnetic resonance (NMR) transitions). Transitions 69C3, 69C4, 69D3 and 69D4 are examples of transitions in which only a nuclear spin flips;
cross transitions in which both an electron or hole spin and a nuclear spin flip. (e.g. EDSR transitions). Transitions 69C5, 69C6, 69D5 and 69D6 are examples of cross transitions.
transitions are also possible between states which include a bound exciton and states which do not include a bound exciton.
transitions are also possible between states which include a bound exciton and states which do not include a bound exciton (e.g. transitions from one of states 66A, 66B, 66C, 66D to one of states 67A, 67B, 67C, 67D.

In a quantum system such as a T center which includes plural nuclear spins, the energy levels of the transitions will, in general, be different for different ones of the nuclear spins. A particular available nuclear spin may be selected for a quantum interaction with another qubit by a selected one of the above transitions by coupling the nuclear spin to the other qubit as described herein such that a transition between quantum states of the other qubit involves an energy difference that matches the energy difference of the selected transition.

In a quantum system such as a T center which has an unpaired electron and supports bound exciton states quantum information may be stored the unpaired electron or in a hole of the bound exciton. As described below the energy differences of transitions involving a hole are different from the energy differences of transitions involving the electron. The electron or hole spin may be selected for a quantum interaction with another qubit by a selected one of the above transitions by coupling the system which includes the electron or hole to the other qubit as described herein such that a transition between quantum states of the other qubit involves an energy difference that matches the energy difference of the selected transition for the electron or the hole.

Any of transitions 69C1, 69C2, 69C3, 69C4, 69C5, 69C6, 69D1, 69D2, 69D3, 69D4, 69D5, and 69D6 may be used to encode quantum information in an electron or hole spin or in a nuclear spin or in a combination of two or more of these. These transitions respectively correspond to energies ΔE_{C1}, ΔE_{C2}, ΔE_{C3}, ΔE_{C4}, ΔE_{C5}, ΔE_{C6}, ΔE_{D1}, ΔE_{D2}, ΔE_{D3}, ΔE_{D4}, ΔE_{D5}, and ΔE_{D6}. For a T center, these energies correspond to photons having frequencies of about 1 MHz to 100 MHz for ΔE_{C5}, ΔE_{C6}, ΔE_{D5}, and ΔE_{D6} and of about 1 GHz to about 100 GHz for ΔE_{C1}, ΔE_{C2}, ΔE_{C3}, ΔE_{C4}, ΔE_{D1}, ΔE_{D2}, ΔE_{D3}, and ΔE_{D4}.

In some embodiments, a nuclear spin and an electron or hole spin in a T center are initialized to a known quantum state. A spin may be set to a desired state, for example by optically pumping the spin to a desired energy level and/or by applying pulses to flip the spin (“pi pulses”). For example, the initial state may be |0 ↓ [symbol] . Subsequently the T center is coupled to a waveguide that may contain a photon having energy ΔE_{C1}. The coupling may be achieved by controlling the wavelength of the photon, controlling ΔE_{C1} and/or controlling a coupling mechanism as described elsewhere herein.

The photon may cause a transition to the state |0 ↑ [symbol] . The photon may be in a superposition of states (e.g. present and not present). The result is that the system of the nuclear spin and the electron or hole spin may end up in a specific superposition of states |0 ↓ [symbol] and |0 ↑ [symbol] that encodes quantum information from the photon state. If the photon couples to the luminescent centre via an available cross transition, both the nuclear spin and the electron or hole spin flip upon the absorption or emission of a photon. These transitions can thus be used to generate specific superpositions of states |0 ↓ [symbol] and |0 ↑ [symbol] . As part of the entangled state, the nuclear spin, considered on its own is in a spin mixture of the states | [symbol] and | [symbol] .

Another example applies a driven-transition to store a quantum state in a nuclear spin of a T center or other crystal defect that includes a nuclear spin and an electron or hole spin. In this example an electron or hole spin is initially in a particular quantum state (e.g. spin up, spin down or a superposition of spin up and spin down). The quantum state of the electron or hole spin may be set, for example, by causing a quantum state transfer between a short lived qubit and the electron or hole spin as described elsewhere herein.

If desired, an available nuclear spin may be initialized to a known state e.g. spin down or spin up. The T center may then be illuminated with photons from an external source (e.g. a laser) that have a wavelength matching the energy of a spin transition that involves the nuclear spin. In some cases the transition is a cross transition that also involves the electron or hole. In a T center or other crystalline defect where there are plural nuclear spins, which one of the nuclear spins undergoes quantum interaction with the electron or hole spin may be selected by the energy of the photons that illuminate the T center. The photons may be provided in the form of a coherent pi pulse. Using a transition triggered by a pi pulse is an efficient way to store an electron or hole spin state in a nuclear spin.

In EDSR a transition occurs in which both an electron spin and a nuclear spin flip. An EDSR transition starting with the state |↓ [symbol] will yield the state |↑ [symbol] . EDSR transitions advantageously couple strongly to electrical fields. Some embodiments apply EDSR transitions to transfer a quantum state of an electron spin to a nuclear spin state and/or to transfer a quantum state of the nuclear spin to an electron or hole spin state and/or to entangle quantum states of an electron or hole spin and a nuclear spin. In some such embodiments the nuclear spin and the electron or hole spin are in a T center.

The present description explains various ways to use an electron spin by coupling the quantum state of the electron spin with the quantum state of a nuclear spin. In general, where a bound exciton that includes a hole spin is present, the hole spin may be coupled with the nuclear spin in the same ways described herein except that the energy levels of a hole spin in a bound exciton will generally differ from the energy levels of an electron spin.

A main reason for the difference in energy levels between an electron spin and a hole spin is that, depending on the environment of the hole, the g-factor for the hole can differ from the g factor for an electron by up to at least a factor of two (e.g. while the g factor for an electron is 2; the g factor for a hole may be in the range of about 1 to 4 depending on the environment of the hole). The energy levels typically scale roughly linearly with the g factor. The same mechanisms described herein for varying ΔE for flipping the spin of an electron may also be applied for varying ΔE for flipping the spin of a hole.

As another example one could use the transition |0 ↓ [symbol] to |0 ↑ [symbol] using a photon having energy ΔEcs. The coupling may be achieved by controlling the wavelength of the photon, controlling ΔE_{C5} and/or controlling a coupling mechanism as described elsewhere herein.

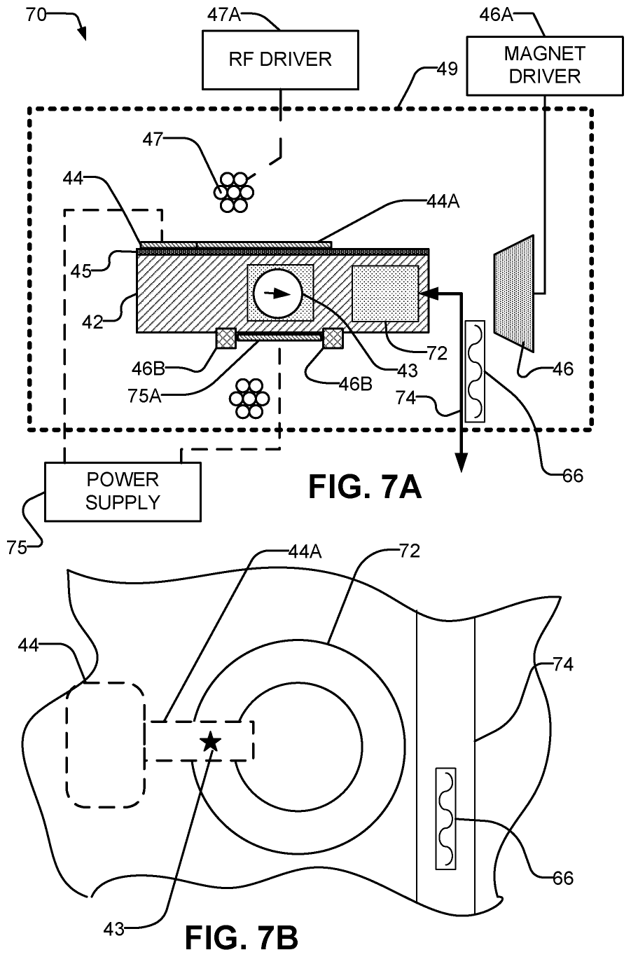

FIGS. 7A and 7B schematically illustrate a system 70 in which a long lived qubit 16 is arranged for coupling to optical photons 66. System 70 has elements in common with system 40 of FIG. 4. These elements are referred to by the same references in FIG. 7 as in FIG. 4.

In system 70 long lived qubit 16 is provided by a luminescent center 43 that is located in or very close to an optical resonator 72. Optical resonator 72 is designed to have a resonant frequency that corresponds to the frequency of photons having energy ΔE1 or ΔE2 (see FIG. 6). Advantageously, long lived qubit 16 may be located inside the optical resonator at a mode maximum of the optical electric field.

Optical resonator 72 may have any suitable structure. Various designs of optical resonator are known. System 70 may incorporate any optical resonator suitable for integration with a substrate 42 which includes a luminescent center 43. In FIG. 7A, optical resonator 72 comprises a ring resonator. Resonator 72 may, for example, be made as described in Tait, et al, arXiv:2001.05100 which is hereby incorporated herein by reference for all purposes. A microring resonator may, for example, be fabricated on a silicon-on-insulator (SOI) platform that comprises a thin (e.g. ˜200-500 nm thick) silicon layer (ideally silicon-28). The silicon-28 layer may be formed on a thicker (e.g. ˜3 μm thick) silicon oxide layer on a host silicon wafer (the silicon wafer may have a natural isotopic concentration of silicon). In some embodiments photons at or very close to the resonant frequency of resonator 72 have whispering gallery modes.

Optical resonator 72 is optically coupled to an optical waveguide 74 by way of which optical photons 66 can be introduced into resonator 72 or carried from resonator 72 to other locations.

Long lived qubit 16 has a location and orientation that are selected to permit sufficient coupling between photons 66 and long lived qubit 16. For example, in some embodiments, long lived qubit 16 is located on an axis that corresponds to a center of a microring resonator and extends perpendicular to a plane of the microring resonator. In some embodiments, long lived qubit 16 has a depth that is 500 nm or less from a material interface. In some embodiments, long lived qubit 16 has a depth in a silicon on insulator device layer that is approximately half way through the silicon on insulator device layer.

The coupling between long lived qubit 16 and photons 66 in optical resonator 72 may be adjusted by controlling ΔE1 or ΔE2 and/or the resonant frequency of optical resonator 72 such that the optical frequency of optical resonator 72 closely matches one of ΔE1 and ΔE2.

ΔE1 and ΔE2 may be adjusted, for example, by varying the strength of an electromagnetic field at the location of long lived qubit 16. In the illustrated embodiment this is achieved by controlling a power supply 75 to apply an electrical potential difference between part 56 and an electrical conductor 75A.

The resonant frequency of resonator 72 may be adjusted, for example, by:
varying optical properties of a boundary of resonator 72, for example, by operating a micro electromechanical system (MEMS);
changing the structural properties such as introducing a gas which attaches to the boundary of resonator 72 and alters its interaction with photons 66;
straining resonator 72 by applying a force to substrate 52 or to resonator 72 itself.
changing a driving strength and/or a coupling of long lived qubit 16 to resonator 72 to exploit nonlinear effects in resonator 72.
applying an electromagnetic field to resonator 72.
changing a temperature of resonator 72.

In some embodiments the resonant frequency of optical resonator 72 is swept through a range of frequencies that include ΔE1 or ΔE2.

System 70 applies a quantum transition having an energy difference corresponding to frequencies in the optical range for coupling to optical photons 66. This transition may, for example, include an orbital transition or a transition that creates an exciton. The transition affects the quantum state of a quantum system (e.g. an electron spin, a hole spin, a nuclear spin, a combination of spins, an exciton) that quantum information is stored in. The transition can cause the quantum state of long lived qubit 16 to be entangled with a photon state in optical resonator 72.

In some embodiments long lived qubit comprises plural quantum particles that can individually or collectively store quantum information. For example, long lived qubit 16 may comprise both an electron or hole spin and at least one nuclear spin. The nuclear spin may have a longer coherence time than the electron or hole spin. It may be desirable to store the quantum state of superconducting qubit 12 as a quantum state of the nuclear spin.

In some embodiments quantum state transfer is used to cause a state of a superconducting qubit to be transferred to a quantum state of a nuclear spin. An example way to do this is to transfer the quantum state of superconducting qubit 12 to the quantum state of the electron or hole spin, for example as described above, and to then transfer the quantum state of the electron or hole to the quantum state of the nuclear spin.

Similar methods to the state transfer process described above can be used to cause quantum interactions such a state transfer or entanglement between the long lived spin qubit with a short lived superconducting qubit. For example, both the spin qubit and the superconducting qubit can be prepared into appropriate eigenstates. They can then be made to coherently interact by methods described above, generating two qubit Rabi oscillations similar to those shown in FIG. 2. If this interaction is stopped after an odd number of half Rabi periods, state transfer is achieved. If instead the interaction is stopped after (N/2+¼) Rabi periods where N is an integer, then an entangled state is generated between the two qubits.

An electron spin or hole spin qubit can be used to teleport the quantum state of a superconducting qubit 14 to an optical photon. For example, the electron spin of the long lived qubit can become entangled with an incident photon by initializing the electron into the spin-up state and allowing it to interact with one of the two photons in an entangled pair. This interaction will transfer the entanglement to the electron spin creating a spin-photon entangled state. The electron spin can then be entangled with the superconducting qubit 12 in a method like that described above. After this entanglement has been established, one can make a joint measurement of superconducting qubit 12 and the electron spin qubit in the Bell-State (entangled) basis. The results of those measurements may be applied to select operations to perform on the second photon from the original entangled pair to “feed forward” the state of superconducting qubit 14 to the photon qubit. For example, the result of the measurement may be supplied to classical control electronics which may look up a feed forward operation in a look up table and then control electrical circuits to implement the feed forward operation. The photonic qubit can then transfer that quantum information to a distant electron spin qubit, which can in turn transfer the state to a distant superconducting qubit.

Entanglement of the state of long lived qubit 16 and optical photons 66 facilitates a mechanism for coupling long lived qubit 16 to an external system. Optical photons have energies significantly higher than the thermal energy at room temperature (about 26 meV—given by k_{B}T where k_{B} is Boltzmann's constant and T is the temperature in Kelvins). For example, the energy of a near infrared optical photon having a wavelength of 1 μm wavelength is about 1.2 eV. In this example, the optical photon has an energy that is larger than the room temperature thermal energy by a factor of more than 40. Because of this, optical photons 66 can be transported outside of a refrigerator in which long lived qubit 16 is located without being unduly affected by thermal noise. Using suitable optical fibers or other known photon transport mechanisms, photons 66 may be carried over long distances.

This mechanism may be used to create entanglement between long lived qubit 16 and on, two or more other qubits that may be located remotely from qubit 16. In some embodiments the other qubit(s) with which long lived qubit 16 is caused to be entangled are other long lived qubits 16 as described herein. The long lived qubits 16 may be the same. For example the entangled long lived qubits 16 may be T centers.

In the descriptions above, long lived qubit 16 has been described as being provided by a single luminescent center such as an impurity atom or a crystal defect. This is possible but not required. In any embodiment a long lived qubit may be provided by a plurality of identical or nearly identical luminescent centers. Some advantages of this are better coupling to photons and less need to precisely place an individual luminescent center. An ensemble of long lived qubits 16 can effectively behave as a single more strongly coupled long lived qubit 16.

As an example of the use of an ensemble of long lived qubits which function effectively as a single long lived qubit, in some embodiments a plurality of long lived qubits 16 are located in or closely adjacent to optical resonator 72. The plurality of long lived qubits 16 may, for example, comprise T centers. The plurality of long lived qubits 16 may, for example, be located inside a ring of an optical ring resonator at a mode maximum of the optical electric field of photons at a resonant frequency of the ring resonator.

In some embodiments a long lived qubit is provided by a number of luminescent centers in the range of 1 to about 10⁵ or about 1 to 2000 or about 40 to 1000. The coupling of a photon to an ensemble of N identical long lived qubits tends to increase as \sqrt{N}. However, the larger the number N, the more difficult it is to make the long lived qubits behave identically or nearly identically. If the long lived qubits do not behave identically the coherence time of the ensemble can be reduced. For larger values of N a larger number of spaced apart long lived qubits may have a wider range of environments and may be exposed to the fields of a photon to which they couple at locations where the fields have different strengths than a smaller number of long lived qubits. As a result, N may be chosen to be large enough to attain a desired strength of coupling to photons (microwave or optical photons) while the ensemble still has a coherence time long enough for an intended application.

Where it is desired to use an ensemble of luminescent centers for a long lived qubit it is beneficial for the luminescent centers to be the same as one another and for the luminescent centers to be placed so that the strength of the magnetic or electric fields by way of which the luminescent centers are coupled to photons is similar for all of the luminescent centers included in the long lived qubit 16.

Defect centers, for example, T centers can have any of a number of orientations relative to the crystal lattice in which they are located. For example, T centers can have any of 12 orientations. In some embodiments defect centers having a plurality of different orientations are included in an ensemble which provides a long lived qubit. In some embodiments, defect centers having certain selected orientations are excluded from participating in an ensemble that provides a long lived qubit. This may be done, for example, by selectively shifting energy levels for defect centers having the selected orientations so that these defect centers cannot couple to the photons that the defect centers included in the ensemble can couple to. Energy levels may be shifted for selected orientations of defect centers, for example, by straining the crystal lattice in selected directions.

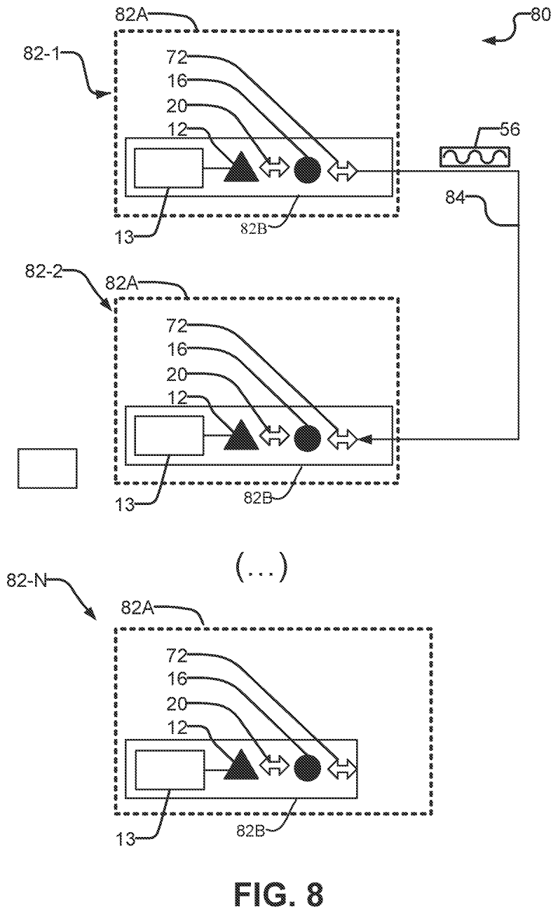

FIG. 8 schematically illustrates an example architecture for a quantum computer system 80 made up of plural modules 82 (modules 82-1, 82-2 to 82-N are illustrated). Each module 82 comprises a refrigerator 82A which cools a quantum computing subsystem 82B that includes one or more short lived qubits 12 each coupled to a corresponding long lived qubit 16 according to any embodiment described herein. Modules 82 may include other environmental control systems such as high vacuum systems, electromagnetic radiation shielding, vibration isolation as required. Short lived qubit 12 may be part of a quantum information processing system 13 that includes other qubits, apparatus for manipulating quantum states of the qubits, information for coupling the qubits in different ways etc. In the illustrated example, long lived qubit 16 is coupled to short lived qubit 12 by a microwave resonator 20.

A photon carrier 84 extends between a long lived qubit 16 of one module 82-1 and a long lived qubit of another module 82-2. Photon carrier 84 may, for example, comprise an optical fiber, optical waveguide, an optical system made up of optical elements such as mirrors, lenses, refractive elements etc. that guides photons 56 through free space etc. Photon carrier 84 provides a path by way of which photons 56 can travel from near one long lived qubit 16, exiting the refrigerator 82A that houses the one long lived qubit 16, passing to the refrigerator 82A that houses a second long lived qubit 16, enter the refrigerator that houses second long lived qubit 16 and interact with the second long lived qubit 16. Through this mechanism quantum states of the first and second long lived qubits 16 may be entangled. Photon carrier 84 may optionally be connected to carry photon states to plural destinations which collectively host plural remote qubits so that long lived qubit 16 can be simultaneously entangled with the plural remote qubits by optical photon states in photon carrier 84.

In some embodiments any module 82 may include two or more long lived qubits 16 that are coupled to corresponding long lived qubits 16 in one or more other modules 82. In such embodiments a single photon may entangle two, three, four or more long lived qubits 16 some or all of which may be in different modules 82.

The general architecture of system 80 is advantageous because it allows the qubits (e.g. short lived qubits 12) of a quantum computer to be distributed among plural refrigerators 82A. This is beneficial because making a refrigerator large enough to house a large quantum computer while cooling components of the quantum computer to necessary low temperatures presents extreme difficulties and also presents operational challenges. In addition, the possibility of making system 80 with photon carriers 84 that have extended length may be used to distribute modules 82 widely. System 80 may, for example, have application in securely distributing quantum information among widely distributed modules 82.

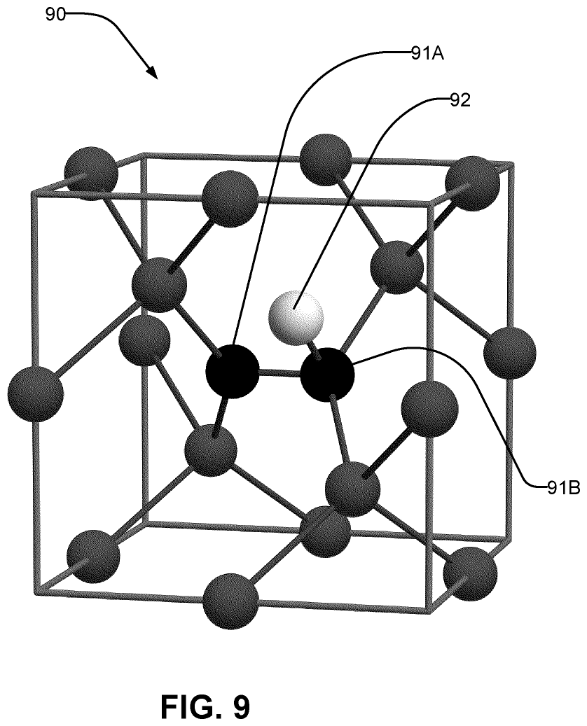

In the embodiments discussed above, it has been found that T centers can be advantageous for use as long lived qubits 16. FIG. 9 illustrates the structure of a T center 90. The T center is a location where a silicon atom in a silicon crystal has been replaced by two carbon atoms 91A and 91B and a hydrogen atom 92 bonded to carbon atom 91B. Carbon atom 91A has one unpaired electron. The spin state of the unpaired electron of carbon atom 91A may be used as a long lived qubit 16.

A T center can also host bound excitons. A number of bound excitons (e.g. 0 or 1) may be used as a long lived qubit 16. A spin state of a hole in a bound exciton may also be used as a long lived qubit 16 or as an intermediate state used to encode quantum information in a nuclear spin.

Bound excitons may be created and destroyed so that they are present only when desired. An exciton may be used to receive quantum information from an external source (such as an optical photon or microwave photon) and to transfer that quantum information to a spin manifold such as a nuclear spin which has a very long coherence time for quantum information. The wave function for a hole in a bound exciton has a relatively large spatial extent which facilitates coupling of the spin of the hole to photons as described elsewhere herein.

T centers have the following properties that make them particularly good for use as long lived qubit 16:
T centers exhibit long spin coherence times (>2.1 ms electron and >1 s nuclear spin);
T centers have narrow optical linewidths (<30 MHz);
T centers can couple to O-band photons (wavelengths including about 1326 nm);
A T center can provide multiple (e.g. 4) accessible spin manifolds;
A T center couples weakly but controllably to lattice strain;
A T center couples weakly but controllably to electric fields;
A T center can support excitons which may be used to store quantum information (e.g. in hole spins).

T centers may be formed in a silicon body by irradiating the silicon body with high energy carbon and high energy hydrogen. This irradiation is followed by high temperature annealing to activate T center formation. In some embodiments T centers are formed at desired locations within a silicon body by applying a hard mask to the silicon body and irradiating the desired locations through apertures in the hard mask.

As mentioned above, T centers have several accessible spin manifolds. These include:
one unpaired electron spin;
one exciton hole spin (if an exciton is present);
one hydrogen nuclear spin; and
two carbon nuclear spins.
   It is possible to store quantum information as in quantum states of any of these spins.

Quantum information may be stored in any of the nuclear spin manifolds. This may be done by various methods. These methods may be applied to store the same or different quantum information in each of two or more of the nuclear spin manifolds. In some embodiments, quantum information from a microwave or optical photon is encoded in the quantum state of an electron or hole spin state as described elsewhere herein. Subsequently, the quantum information is encoded in the spin state of one of the nuclear spins. In some embodiments, quantum information from a microwave or optical photon is simultaneously encoded in spin states of an electron or hole spin and one or more nuclear spins.

In general, in a quantum system which includes an electron or hole spin and a plurality of different nuclear spins (a T center being one example of such a system) the various spin transitions can be selected by the frequency of photons involved in the interaction. For each pair of an electron or hole spin and a nuclear spin a set of energy levels is available. These energy levels may be identified for example as:
   |↓ [symbol] >with energy=0;
   |↓ [symbol] >with energy=NMR1;
   |↑ [symbol] >with energy=EPR1; and
   |↑ [symbol] >with energy=NMR2+EPR1;
   where the single arrow represents electron or hole spin and the double arrow represents nuclear spin. These energy levels are usually different for different nuclear spins which allows individual nuclear spins to be selected for such transitions. Transitions between these energy levels may be combined with orbital transitions and/or creation or annihilation of a bound exciton. Such combinations will also usually correspond to different energies depending on which of the plurality of nuclear spins is participating.

Individual nuclear spins may be selectively initialized to have a desired spin state (e.g. spin up) by, for example, optically cycling the spin-down electron state while simultaneously applying RF tones selected to stimulate an electron flip transition (e.g. tones having frequencies corresponding to energy EPR2 that connect |0 ↓ [symbol] > to |0 ↑ [symbol] Relaxation from the excited state |1↑> may occur by a mechanism that flips either the nuclear spin or the electron spin, the electron will eventually accumulate probability of having flipped, but if the nuclear spin is spin up when the electron flips to a spin up state the EPR1 RF tones will drive the electron to return back to the spin down state. If the resulting state has a spin-down electron, it is rapidly re-excited by the optical field. Similarly, if the system relaxes into |0 ↓ [symbol] >, then the EPR2 field returns the electron to the spin-down state at which point it is rapidly re-excited. Only the |0 ↑ [symbol] > state is not rapidly re-excited so the system initializes into that state. Where there are plural nuclear spins the energy EPR2 will be different for different nuclear spins. It is possible to select which of the plural nuclear spins to initialize by applying RF tones which correspond to the value of EPR2 for the selected nuclear spin.

Another way to initialize a nuclear spin to a desired state is to measure the nuclear spin and, if the nuclear spin is not already in a desired spin state, apply pi pulses to cause the nuclear spin to be in the desired spin state.

As an example application of the technology described herein, one could place a superconducting qubit into a particular state. This may be done, for example, by performing quantum computations in a quantum computer of which the superconducting qubit is a part. One could then a store the quantum state of the superconducting qubit in the electron spin of a T center and then transfer the quantum state to the longer-lived hydrogen nuclear spin of the T center. One could repeat this process for each of the carbon nuclear spins of the T center. This process can store up to three states of the superconducting qubit, optionally operate on the stored states as spins, and subsequently retrieve any of the three states to the superconducting qubit as needed. In addition, any of the three states could be transferred to an optical photon and transported anywhere.

In some embodiments plural nuclear spins in a T center or other crystal defect are applied for quantum error correction. For example, the techniques described herein may be applied to use plural nuclear spins for majority voting local error correction. The qubit state of interest may be stored in one nuclear spin according to any of the examples described herein. Two or more other nuclear spins may then be used as ancillas for encoding the state of interest in a logical qubit for error correction or error detection. The error correction may operate, for example, as described in Waldherr, et al Quantum error correction in a solid-state hybrid spin register, Nature 506, 204-207 (2014) which is hereby incorporated herein by reference.

In some embodiments long lived qubits 16 such as T centers are applied for entanglement purification. In such embodiments electron or hole spins may be used as operational qubits and nuclear spins may be used as memory qubits. Consider, for example the case where it is desired to create entanglement among quantum states at two or more nodes, which may be distant from one another. Each node may include a long lived qubit 16 which includes an electron or hole spin and at least one nuclear spin. One can establish entanglement between the operational qubits (e.g. using optical photons as described herein). The resulting entanglement may then be transferred to the memory qubits via state transfer as described herein. The operational qubits are then entangled again, but this time that entanglement is mapped onto each memory qubit via a conditional operation at each node. By repeating this sequence, and by performing appropriate measurements, the memory qubits at different nodes can be caused to be entangled with a very high purity. That entanglement can then be mapped back on to the operational qubit(s) if desired. A reference that describes the basic principles of quantum purification that may be applied using long lived qubits 16 as described herein is Kalb, et al, Science 356, 928-932 (2017) which is hereby incorporated herein by reference.

In some of the examples given above the short lived qubit is a superconducting qubit. The present technology may also be applied in the case where the short lived qubit is another type of qubit such as a quantum dot or an ion trap. For the case where the short lived qubit is provided by a quantum dot the quantum dot may be located relative to other structures (e.g. resonators, optical structures, a long lived qubit, a silicon substrate in which the long lived qubit is located, etc.) as described herein. In the case where the short lived qubit comprises an ion trapped by magnetic fields (i.e. an ion trap qubit) the magnetic fields may be configured to trap the ion adjacent to a surface of a device that includes the long lived qubit at a location that is near to a resonator and/or the long lived qubit such that the ion trap qubit may be coupled to the long lived qubit as described herein.

The methods and systems described herein may be applied to any quantum information processing system. For example, short lived qubits 12 may be part of any currently known or future developed quantum information processing system.

A system which includes the technology described herein may also include a non-quantum computer system configured to control a set of qubits to perform quantum computations by performing functions such as:
setting states of the qubits,
manipulating states of the qubits,
causing quantum states of different ones of the qubits to become entangled with one another, and/or
performing quantum measurements.

Such a non-quantum computer system may be configured to perform the above functions to implement commands in a programming language suitable for quantum computing. The non-quantum computer system may be implemented using specifically designed hardware, configurable hardware, programmable data processors configured by the provision of software (which may optionally comprise “firmware”) capable of executing on the data processors, special purpose computers or data processors that are specifically programmed, configured, or constructed to perform one or more steps in a method as explained in detail herein and/or combinations of two or more of these. Examples of specifically designed hardware are: logic circuits, application-specific integrated circuits (“ASICs”), large scale integrated circuits (“LSIs”), very large scale integrated circuits (“VLSIs”), and the like. Examples of configurable hardware are: one or more programmable logic devices such as programmable array logic (“PALs”), programmable logic arrays (“PLAs”), and field programmable gate arrays (“FPGAs”). Examples of programmable data processors are: microprocessors, digital signal processors (“DSPs”), embedded processors, graphics processors, math co-processors, general purpose computers, server computers, cloud computers, mainframe computers, computer workstations, and the like. For example, one or more data processors in a control circuit for a device may implement methods as described herein by executing software instructions in a program memory accessible to the processors.

The non-quantum computer system may be centralized or distributed. Where processing is distributed, information including software and/or data may be kept centrally or distributed. Such information may be exchanged between different functional units by way of a communications network, such as a Local Area Network (LAN), Wide Area Network (WAN), or the Internet, wired or wireless data links, electromagnetic signals, or other data communication channel.

The skilled person reading this disclosure will understand that the technology described above has many aspects and applications. These include, without limitation:
A. Apparatuses and methods operative to transduce quantum information from a first qubit to one or more third qubits using a second qubit provided by a quantum system which has a first pair of quantum states having a first energy difference corresponding to a microwave frequency and a second pair of quantum states having a second energy difference corresponding to an optical frequency. The method causes quantum interaction between the first and second qubits mediated by microwave photon states at the microwave frequency to entangle the first and second qubits and/or to transfer all or part of a quantum state of the first qubit to the second qubit. The method subsequently causes quantum interaction between the second qubit and one or more third qubits mediated by optical photon states at the optical frequency to entangle the second and third qubits and/or to transfer a quantum state of the second qubit to the third qubit. The first qubit may, for example, be provided by a superconducting circuit, a quantum dot or an ion trap, In some embodiments the second qubit is provided by a defect center in silicon such as a T center. The first pair of quantum states may, for example, comprise: up and down spin states of an unpaired electron in the T center, up and down spin states of a nuclear spin in the T center, spin states of a multi-particle spin system (e.g. a spin state of an unpaired electron spin and a nuclear spin) separated by a spin flip transition. The second pair of quantum states may, for example comprise states separated by an orbital transition or a transition which creates an exciton where the transition has an energy that is different if the transition is performed when the second qubit is in one of the quantum states of the first pair than if the transition is performed when the second qubit is in the other one of the quantum states of the first pair. In some embodiments the first second and third qubits are parts of a quantum computer.
B. Apparatus and methods which store quantum information in a defect center in silicon. In some embodiments the defect center is a T center. In some embodiments quantum information is received from a first qubit, stored in the defect center and subsequently returned to the first qubit. In some embodiments the quantum information is stored in the defect center for a time longer than a coherence time of the first qubit. In some embodiments the first qubit comprises a superconducting circuit or a quantum dot or an ion trap. In some embodiments the quantum information is transferred from the defect center to a third qubit. In some embodiments the quantum information is manipulated while it is being stored in the defect center.
C. Apparatus and methods which store quantum information in a T center in silicon. In some embodiments the quantum information is stored in a spin state of an unpaired electron in the T center. In some embodiments the quantum information is stored in a spin state of an nuclear spin in the T center. In some such embodiments the quantum information is transferred directly to the nuclear spin from a first qubit. In some embodiments the quantum information is transferred from the first qubit to a spin state of an unpaired electron in the T center and subsequently transferred from the spin state of the unpaired electron to the nuclear spin state. In some embodiments a T center is used to simultaneously store two or three or four sets of quantum information in two or three or four of the four spin states of a T center (three nuclear spins and one unpaired electron spin). In some embodiments the same quantum information is stored in two or three or four of the spin states of the T center. In some embodiments the same quantum information is stored in three or more spin states of the T center and two or more of the spin states are used for quantum error correction.
D. Apparatus and methods which use an ensemble of atomically identical crystal defects in silicon to store quantum information. In some embodiments the crystal defects are T centers.
E. Apparatus and methods for quantum computing in a quantum computer system having a plurality of qubits distributed among a plurality of physically separate controlled environments. The controlled environments may, for example comprise ultra low temperature and/or high vacuum environments. The quantum information may be transferred among qubits in different ones of the separate controlled environments using the technology as described herein.
F. Apparatus and methods for entangling or transferring quantum interaction between physically separated qubits that store quantum information in quantum states that are separated by energies of 1.3 meV or less. The methods involve transducing some or all of the quantum information from a first qubit into optical photons by coupling the first qubit to a second qubit by microwave photons and then coupling the second qubit to the optical photons. In some embodiments the second qubit is a lunminescent center in silicon. For example, the second qubit may comprise an impurity atom, a defect center (e.g. a T center), or an ensemble of atoms or defect centers.

### Interpretation of Terms

Unless the context clearly requires otherwise, throughout the description and the claims:
“comprise”, “comprising”, and the like are to be construed in an inclusive sense, as opposed to an exclusive or exhaustive sense; that is to say, in the sense of “including, but not limited to”;
“connected”, “coupled”, or any variant thereof, means any connection or coupling, either direct or indirect, between two or more elements; the coupling or connection between the elements can be physical, logical, or a combination thereof;
“herein”, “above”, “below”, and words of similar import, when used to describe this specification, shall refer to this specification as a whole, and not to any particular portions of this specification;
“or”, in reference to a list of two or more items, covers all of the following interpretations of the word: any of the items in the list, all of the items in the list, and any combination of the items in the list;
the singular forms “a”, “an”, and “the” also include the meaning of any appropriate plural forms.

Words that indicate directions such as “vertical”, “transverse”, “horizontal”, “upward”, “downward”, “forward”, “backward”, “inward”, “outward”, “left”, “right”, “front”, “back”, “top”, “bottom”, “below”, “above”, “under”, and the like, used in this description and any accompanying claims (where present), depend on the specific orientation of the apparatus described and illustrated. The subject matter described herein may assume various alternative orientations. Accordingly, these directional terms are not strictly defined and should not be interpreted narrowly.

Where a component (e.g. a software module, processor, assembly, device, circuit, etc.) is referred to above, unless otherwise indicated, reference to that component (including a reference to a “means”) should be interpreted as including as equivalents of that component any component which performs the function of the described component (i.e., that is functionally equivalent), including components which are not structurally equivalent to the disclosed structure which performs the function in the illustrated exemplary embodiments of the invention.

Where a method is described herein that includes a sequence of steps and/or acts, alternative examples may perform the steps and/or acts in a different order. Some processes or blocks may be deleted, moved, added, subdivided, combined, /or modified and/or taken in subcombinations to provide alternative embodiments. Also, each step or act may be implemented in a variety of different ways. Also, while steps or acts are at times shown as being performed in series, these steps or acts may instead be performed in parallel, or may be performed at different times.

Specific examples of systems, methods and apparatus have been described herein for purposes of illustration. These are only examples. The technology provided herein can be applied to systems other than the example systems described above. Many alterations, modifications, additions, omissions, and permutations are possible within the practice of this invention. This invention includes variations on described embodiments that would be apparent to the skilled addressee, including variations obtained by: replacing features, elements and/or acts with equivalent features, elements and/or acts; mixing and matching of features, elements and/or acts from different embodiments; combining features, elements and/or acts from embodiments as described herein with features, elements and/or acts of other technology; and/or omitting combining features, elements and/or acts from described embodiments.

Various features are described herein as being present in “some embodiments”. Such features are not mandatory and may not be present in all embodiments. Embodiments of the invention may include zero, any one or any combination of two or more of such features. This is limited only to the extent that certain ones of such features are incompatible with other ones of such features in the sense that it would be impossible for a person of ordinary skill in the art to construct a practical embodiment that combines such incompatible features. Consequently, the description that “some embodiments” possess feature A and “some embodiments” possess feature B should be interpreted as an express indication that the inventors also contemplate embodiments which combine features A and B (unless the description states otherwise or features A and B are fundamentally incompatible).

It is therefore intended that the following appended claims and claims hereafter introduced are interpreted to include all such modifications, permutations, additions, omissions, and sub-combinations as may reasonably be inferred. The scope of the claims should not be limited by the preferred embodiments set forth in the examples, but should be given the broadest interpretation consistent with the description as a whole.

1. A method for storing quantum information, the method comprising:
providing a first qubit in a first quantum state that encodes first quantum information, the first qubit having first and second quantized energy levels separated by an energy ΔE_{SQ} corresponding to a microwave frequency;
coupling the first qubit to a first luminescent center in silicon by way of a microwave photon state such that quantum states of the first qubit and the first luminescent center undergo a quantum interaction wherein the quantum state of the first luminescent center encodes the first quantum information.

2. The method according to claim 1 comprising coupling the first qubit to the first luminescent center for a time that is substantially equal to n half periods of a two qubit Rabi frequency of the first qubit and the first luminescent center wherein n is an odd integer and uncoupling the first qubit from the first luminescent center.

3. (canceled)

4. The method according claim 1 wherein the first luminescent center has first and second quantized energy levels separated by an energy ΔE_{LC1} and coupling the first qubit to the first luminescent center comprises adjusting one or both of the energy ΔE_{LC1} and the energy ΔE_{SQ} so that ΔE_{LC1} and ΔE_{SQ} are substantially equal.

5. The method according to claim 4 comprising adjusting the energy ΔE_{LC1}.

6.-8. (canceled)

9. The method according to claim 1 wherein the first luminescent center possesses a third energy level separated from the first energy level by an energy difference ΔE_{LC2} and the method comprises coupling the quantum state of the first luminescent center to an optical photon state in a first resonator having a resonant frequency corresponding to ΔE_{LC2} such that the photon state in the first resonator encodes the first quantum state.

10.-11. (canceled)

12. The method according to claim 9 comprising delivering a photon of the photon state to a second resonator and coupling the second resonator to a second luminescent center such that a quantum state of the second luminescent center encodes the first quantum information.

13. The method according to claim 9 wherein the photon state in the first resonator is entangled with another photon state in a second resonator and the method comprises coupling the second resonator to a second luminescent center such that a quantum state of the second luminescent center encodes the first quantum information.

14. The method according to claim 12 comprising encoding the first quantum information in a quantum state of a second matter qubit by coupling the second luminescent center to the second matter qubit by way of another microwave photon state wherein quantum states of the second matter qubit and the second luminescent center engage in a quantum interaction such that the quantum state of the second matter qubit encodes the first quantum information.

15.-16. (canceled)

17. The method according to claim 2 comprising returning the first quantum information to the first qubit by coupling the first luminescent center to the first qubit by way of another microwave photon state such that quantum states of the first qubit and the first luminescent center engage in a quantum state transfer interaction such that the quantum state of the first qubit encodes the first quantum information.

18. The method according to claim 1 wherein the first luminescent center comprises a crystal defect in a silicon crystal.

19. (canceled)

20. The method according to claim 18 wherein the crystal defect comprises a T center.

21. (canceled)

22. The method according to claim 18 wherein the crystal defect comprises at least one of an electron having an electron spin and a hole having a hole spin and the first and second quantized energy levels of the first luminescent center respectively comprise spin down and spin up states of the electron or hole.

23. The method according to claim 22 wherein the crystal defect comprises at least one nuclear spin and the method further comprises encoding a quantum state of the electron or hole in a quantum state of the nuclear spin such that the nuclear spin encodes the first quantum information.

24. The method according to claim 18 wherein the crystal defect comprises at least one unpaired electron or hole spin and at least one nuclear spin and the method further comprises encoding the first quantum information in a joint quantum state of the at least one unpaired electron or hole spin and the at least one nuclear spin.

25.-26. (canceled)

27. The method according to claim 24 further comprising recovering the first quantum information by setting the unpaired electron or hole spin to have an initialized quantum state and causing a spin transition of the unpaired electron or hole spin and/or the nuclear spin.

28. The method according to claim 22 wherein the crystal defect comprises a plurality of nuclear spins and the method comprises:
encoding the first quantum information in a first one of the nuclear spins;
causing the first qubit to encode second quantum information;
coupling the first qubit to the first luminescent center by way of a second microwave photon state such that quantum states of the first qubit and an electron or hole of the first luminescent center undergo a quantum interaction and the quantum state of the electron or hole of the first luminescent center encodes the second quantum information;
uncoupling the first qubit from the first luminescent center; and
encoding the quantum state of the electron or hole in a quantum state of a second one of the nuclear spins such that the second one of the nuclear spins encodes the second quantum information.

29.-34. (canceled)

35. The method according to claim 14 wherein the first qubit is in a first refrigerator and the second matter qubit is in a second refrigerator and the first and second resonators are connected by an optical path that passes outside of the first and second refrigerators.

36. The method according to claim 35 wherein at least a portion of the optical path that is outside of the first and second refrigerators is at a temperature that is greater than ΔE_{SQ}/k_{B} where k_{B} is Boltzmann's constant.

37.-38. (canceled)

39. The method according to claim 1 wherein the first qubit is a superconducting qubit.

40. The method according to claim 1 wherein the first qubit comprises a quantum dot or an ion trap.

41.-82. (canceled)
